(19) United States
(12) Patent Application Publication
(10) Pub. No.: US 2015/0376000 A1
(43) Pub. Date: Dec. 31, 2015

(54) METHOD FOR REDUCING DISCHARGE DEFECTS AND ELECTRODE DELAMINATION IN PIEZOELECTRIC OPTICAL MEMS DEVICES

(71) Applicant: Texas Instruments Incorporated, Dallas, TX (US)

(72) Inventors: YungShan Chang, Plano, TX (US); Ricky A. Jackson, Richardson, TX (US); Joel Soman, Dallas, TX (US)

(21) Appl. No.: 14/534,012

(22) Filed: Nov. 5, 2014

Related U.S. Application Data
(60) Provisional application No. 62/018,807, filed on Jun. 30, 2014.

(51) Int. Cl. B81C 1/00

(52) U.S. Cl. CPC B81C 1/00698; B81C 1/0038

(57) ABSTRACT

A method includes forming a piezoelectric optical micro-electromechanical system (MEMS) device having a piezoelectric capacitor over a lens material. The lens material forms a lens, and the piezoelectric capacitor is configured to change a shape of the lens material in order to change a focus of the lens. The piezoelectric capacitor includes first and second electrodes separated by at least one piezoelectric material. The method also includes performing a first anneal on the piezoelectric optical MEMS device in nitrogen gas and performing a second anneal on the piezoelectric optical MEMS device in oxygen gas after performing the first anneal. The method further includes depositing a protective oxide layer over the lens material and the piezoelectric capacitor after performing the second anneal. The first anneal in the nitrogen gas causes the piezoelectric optical MEMS device to be substantially free of discharge defects.

### CROSS-REFERENCE TO RELATED APPLICATION AND PRIORITY CLAIM

This application claims priority under 35 U.S.C. §119(e) to U.S. Provisional Patent Application No. 62/018,807 filed on Jun. 30, 2014, which is hereby incorporated by reference in its entirety.

### TECHNICAL FIELD

This disclosure is generally directed to electrical circuit manufacturing. More specifically, this disclosure is directed to a method for reducing discharge defects and electrode delamination in piezoelectric optical micro-electromechanical system (MEMS) devices.

### BACKGROUND

A piezoelectric material represents a material that generates a voltage when the material changes shape or that changes shape when a voltage is applied to the material. Piezoelectric materials have been used in a wide variety of devices, such as lens actuators. Often times, lens actuators use a piezoelectric material to push or pull a lens in order to cause linear movement of the lens back and forth over a small distance, which changes the focusing of light by the lens.

### SUMMARY

This disclosure provides a method for reducing discharge defects and electrode delamination in piezoelectric optical micro-electromechanical system (MEMS) devices.

In a first embodiment, a method includes performing a first anneal on a structure in nitrogen gas, where the structure includes a lens material and a piezoelectric capacitor over the lens material. The method also includes performing a second anneal on the structure in oxygen gas after performing the first anneal. The method further includes depositing a protective layer over the structure after performing the second anneal.

In a second embodiment, a method includes forming a piezoelectric capacitor over a lens material. The lens material forms a lens, and the piezoelectric capacitor includes first and second electrodes separated by at least one piezoelectric material. The method also includes performing a first anneal on the lens material and the piezoelectric capacitor in nitrogen gas and performing a second anneal on the lens material and the piezoelectric capacitor in oxygen gas after performing the first anneal. The method further includes depositing a protective layer over the lens material and the piezoelectric capacitor after performing the second anneal.

In a third embodiment, a method includes forming a piezoelectric optical micro-electromechanical system (MEMS) device having a piezoelectric capacitor over a lens material. The lens material forms a lens, and the piezoelectric capacitor is configured to change a shape of the lens material in order to change a focus of the lens. The piezoelectric capacitor includes first and second electrodes separated by at least one piezoelectric material. The method also includes performing a first anneal on the piezoelectric optical MEMS device in nitrogen gas and performing a second anneal on the piezoelectric optical MEMS device in oxygen gas after performing the first anneal. The method further includes depositing a protective oxide layer over the lens material and the piezoelectric capacitor after performing the second anneal. The first anneal in the nitrogen gas causes the piezoelectric optical MEMS device to be substantially free of discharge defects.

Other technical features may be readily apparent to one skilled in the art from the following figures, descriptions, and claims.

### BRIEF DESCRIPTION OF THE DRAWINGS

For a more complete understanding of this disclosure and its features, reference is now made to the following description, taken in conjunction with the accompanying drawings, in which:

FIGS. 1A and 1B illustrate an example piezoelectric optical micro-electromechanical system (MEMS) device in accordance with this disclosure;

FIGS. 2A and 2B illustrate example piezoelectric optical MEMS devices created using different annealing processes in accordance with this disclosure;

FIG. 3 illustrates example results obtained using different annealing processes for piezoelectric optical MEMS devices in accordance with this disclosure;

FIG. 4 illustrates an example method for reducing discharge defects and electrode delamination in piezoelectric optical MEMS devices in accordance with this disclosure; and

FIG. 5 illustrates an example device containing a piezoelectric optical MEMS device in accordance with this disclosure.

### DETAILED DESCRIPTION

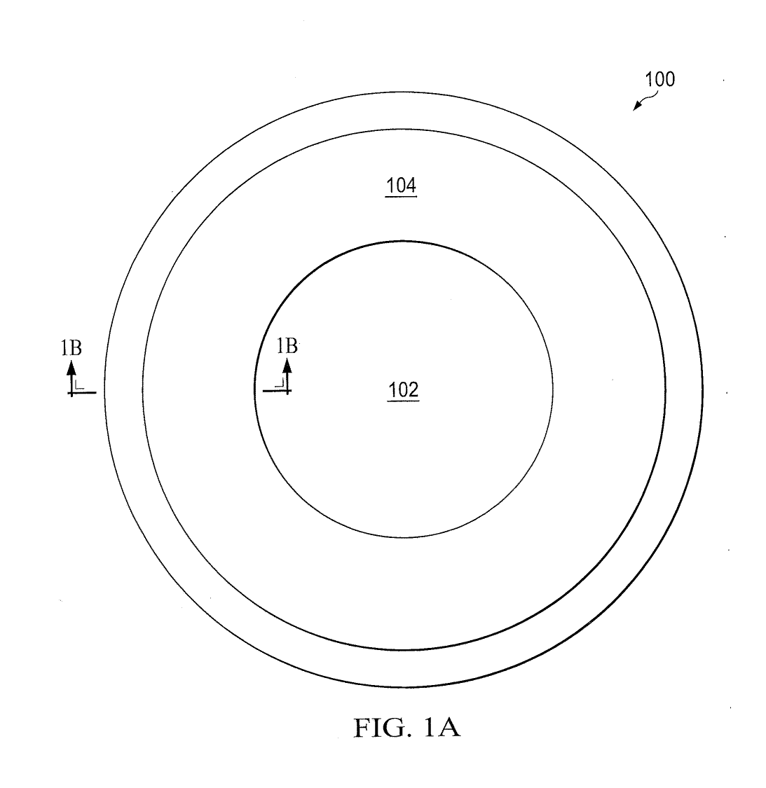

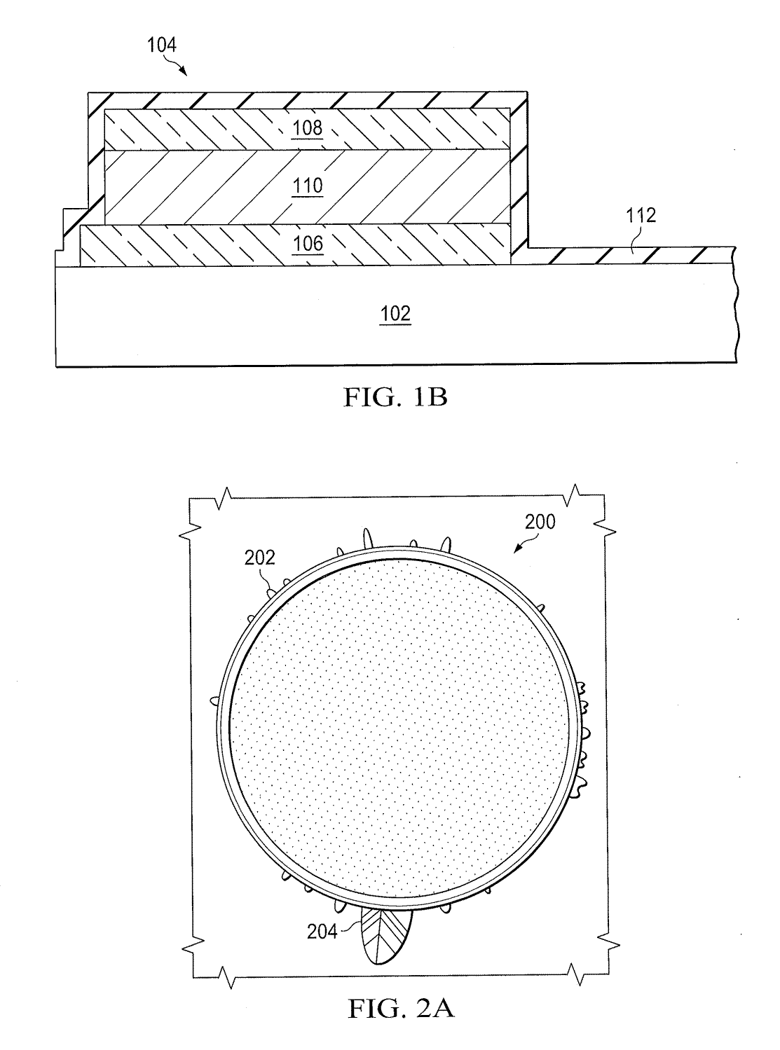

FIGS. 1A through 5, discussed below, and the various embodiments used to describe the principles of the present invention in this patent document are by way of illustration only and should not be construed in any way to limit the scope of the invention. Those skilled in the art will understand that the principles of the present invention may be implemented in any suitable manner and in any type of suitably arranged device or system.

FIGS. 1A and 1B illustrate an example piezoelectric optical micro-electromechanical system (MEMS) device 100 in accordance with this disclosure. In particular, FIGS. 1A and 1B illustrate an example auto-focus lens. FIG. 1A shows a top view of the piezoelectric optical MEMS device 100, and FIG. 1B shows a cross-section of the piezoelectric optical MEMS device 100 taken along the line shown in FIG. 1A.

As shown in FIGS. 1A and 1B, the piezoelectric optical MEMS device 100 includes lens material 102 and a piezoelectric capacitor 104. The lens material 102 generally represents any suitable material or combination of materials that is partially or fully transparent to one or more wavelengths of interest. For example, the lens material 102 could represent glass, such as borophosphosilicate glass (BPSG). The lens material 102 forms a lens and can be deformed to change the focus of the lens. The lens material 102 could include any suitable material(s) and can be formed in any suitable manner, such as via deposition on a silicon or other underlying substrate (at least part of which is later removed).

The piezoelectric capacitor 104 includes a bottom electrode 106, a top electrode 108, and a piezoelectric layer 110. Each electrode 106-108 represents a conductive structure that can be electrically coupled to an external driver or other component(s). Each electrode 106-108 can be formed from any suitable conductive material(s), such as platinum, nickel, palladium, or other metal(s). Each electrode 106-108 could also be formed in any suitable manner, such as via metal deposition followed by an etch process. In addition, each electrode 106-108 could have any suitable size, shape, and dimensions, and the electrodes 106-108 may or may not have the same sizes, shapes, and dimensions.

The electrodes 106-108 are separated by the piezoelectric layer 110 (which is also insulative) to thereby form a capacitor. A voltage applied across the electrodes 106-108 causes the piezoelectric layer 110 to bend, which causes the lens material 102 to bend and change the focus of the lens formed by the lens material 102. The piezoelectric layer 110 includes any suitable piezoelectric material(s), such as lead zirconium titanate (PZT).

A protective layer 112 is formed over the lens material 102 and the piezoelectric capacitor 104. The protective layer 112 represents at least one layer that helps to protect the underlying lens material 102 and piezoelectric capacitor 104. The protective layer 112 could also function as an anti-reflective coating (ARC) layer during subsequent fabrication steps. The protective layer 112 could be formed from any suitable material(s), such as one or more oxides. As a particular example, the protective layer 112 could include a stack containing two silicon dioxide (SiO₂) layers separated by a silicon oxinitride (SiON) layer, although the number of SiO₂, SiON, or other oxide layers could vary. The protective layer 112 could also be formed in any suitable manner. For instance, an initial layer of alumina or other material(s) could be created over the lens material 102 and the piezoelectric capacitor 104, such as by using atomic layer deposition (ALD). The silicon dioxide, silicon oxinitride, or other layers could then be formed over the initial layer.

Although not shown here, various other structures can be fabricated as part of the piezoelectric optical MEMS device 100. For example, a seeding layer could be used to facilitate formation of the layer(s) of material(s) used to form the bottom electrode 106 on the lens material 102, helping to improve adhesion of the bottom electrode 106 to the lens material 102. As another example, electrical contacts (such as those using an aluminum copper/titanium/titanium nitride stack) can be formed and electrically coupled to the electrodes 106-108 through openings in the protective layer 112, and bond pads can be electrically coupled to the electrical contacts. The bond pads can be used to electrically couple the piezoelectric optical MEMS device 100 to an external device or system

Two problems with this type of optical MEMS device involve discharge defects and electrode delamination. Hydrogen exists in many semiconductor fabrication steps, such as during the deposition of hydrogen-containing passivation material (like those used to form the protective layer 112) or during “forming gas” anneal operations. When the electrodes 106-108 of the piezoelectric capacitor 104 are formed using one or more materials having strong catalytic activity (such as platinum, nickel, or palladium), hydrogen can penetrate one or both electrodes 106-108 and chemically interact with the material in the piezoelectric layer 110. This forms oxygen vacancies at one or both interfaces of the electrodes 106-108 and the piezoelectric layer 110. These oxygen vacancies form discharge defects in the piezoelectric optical MEMS device 100, which can (among other things) increase leakage current through and decrease the breakdown voltage of the piezoelectric capacitor 104. If an adequate number of these defects exists, the defects can lead to electrode delamination, where an electrode 106-108 physically separates from the piezoelectric layer 110.

In accordance with this disclosure, an annealing process is performed on the lens material 102 and the piezoelectric capacitor 104 prior to formation of the protective layer 112. The annealing process generally includes an anneal in nitrogen gas (N₂) followed by an anneal in oxygen gas (O₂). An anneal in oxygen gas is routinely performed to help remove defects and repair oxygen vacancies in semiconductor or integrated circuit devices. However, in the case of the piezoelectric optical MEMS device 100, using just an oxygen gas anneal cannot repair the discharge defects present at the interfaces between the electrodes 106-108 and the piezoelectric layer 110.

The nitrogen gas anneal helps to break covalent bonds between oxygen and hydrogen atoms in hydroxyl-contained discharge defects at the interfaces between the electrodes 106-108 and the piezoelectric layer 110. As a result, the subsequent oxygen gas anneal more effectively removes residual defects and provides oxygen to help repair the oxygen vacancies at the interfaces between the electrodes 106-108 and the piezoelectric layer 110. This two-stage thermal anneal process significantly reduces or eliminates electrode delamination, significantly reduces leakage currents in the piezoelectric capacitor 104, and significantly increases breakdown voltages of the piezoelectric capacitor 104.

Although FIGS. 1A and 1B illustrate one example of a piezoelectric optical MEMS device 100, various changes may be made to FIGS. 1A and 1B. For example, the size, shape, dimensions, and number of each component and the arrangement of components in the piezoelectric optical MEMS device 100 are for illustration only and can vary as needed or desired. As a particular example, the electrodes 106-108 need not be circular and could have other shapes, and the electrodes 106-108 need not have the same shape or size. Also, the relative sizes and thicknesses of the various layers shown in FIG. 1B can vary as needed or desired.

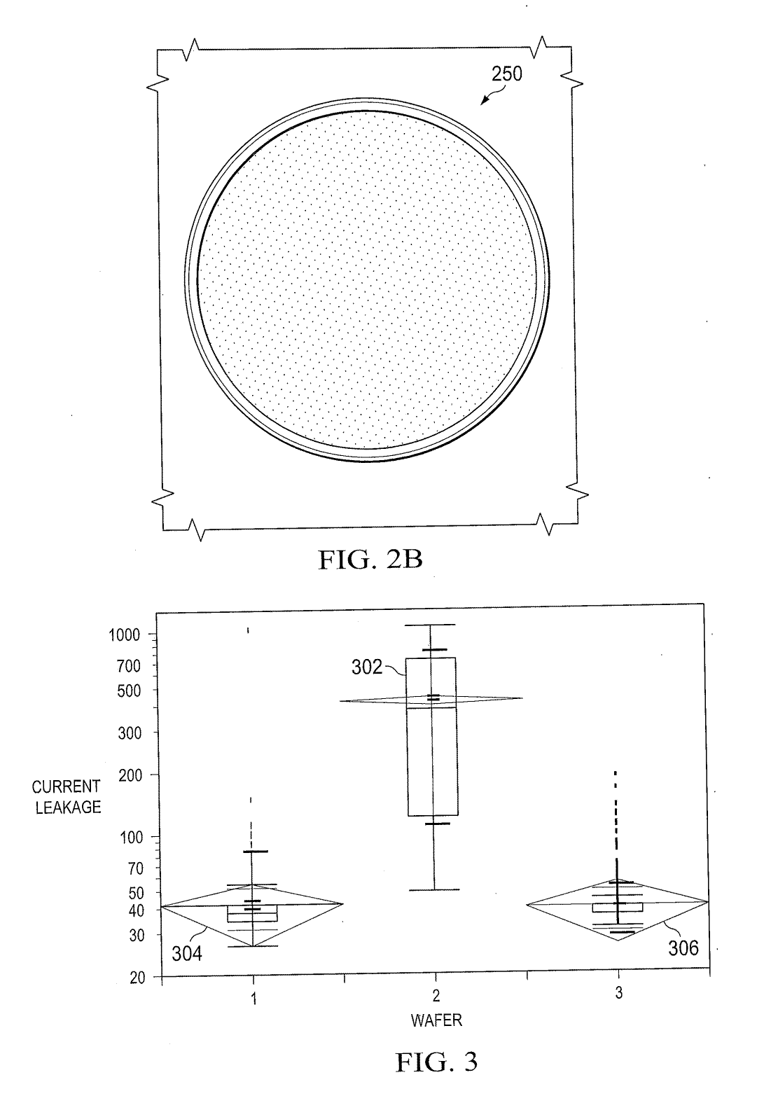

FIGS. 2A and 2B illustrate example piezoelectric optical MEMS devices created using different annealing processes in accordance with this disclosure. In particular, FIG. 2A illustrates a piezoelectric optical MEMS device 200 created using an oxygen gas anneal without a preceding nitrogen gas anneal, and FIG. 2B illustrates a piezoelectric optical MEMS device 250 created using an oxygen gas anneal with a preceding nitrogen gas anneal. The piezoelectric optical MEMS devices 200, 250 could represent specific implementations of the piezoelectric optical MEMS device 100 of FIGS. 1A and 1B, although the piezoelectric capacitors 104 here are thinner radially than the one shown in FIGS. 1A and 1B.

As can be seen in FIG. 2A, the piezoelectric optical MEMS device 200 includes a large number of discharge defects 202. Also, in at least one location, the piezoelectric optical MEMS device 200 has suffered an electrode delamination 204. Among other things, the discharge defects 202 and the electrode delamination 204 can increase the leakage current of the piezoelectric capacitor 104 in the piezoelectric optical MEMS device 200, decrease the breakdown voltage of the piezoelectric capacitor 104 in the piezoelectric optical MEMS device 200, or even render the piezoelectric optical MEMS device 200 non-functional. As noted above, the discharge defects 202 and the electrode delamination 204 are caused by the presence of hydrogen in various preceding fabrication operations, which can create oxygen vacancies at the interfaces of the electrodes 106-108 and the piezoelectric layer 110.

As can be seen in FIG. 2B, the piezoelectric optical MEMS device 250 has virtually no discharge defects and no electrode delamination. This is because the piezoelectric optical MEMS device 250 underwent a nitrogen gas anneal prior to the oxygen gas anneal before the protective layer 112 was formed. The nitrogen gas anneal helps to break covalent bonds between oxygen and hydrogen atoms in discharge defects at interfaces between at least one of the electrodes 106-108 and the piezoelectric layer 110. As a result, the leakage current of the piezoelectric capacitor 104 in the piezoelectric optical MEMS device 250 decreases, the breakdown voltage of the piezoelectric capacitor 104 in the piezoelectric optical MEMS device 250 increases, and the reliability of the piezoelectric optical MEMS device 250 increases.

Although FIGS. 2A and 2B illustrate examples of piezoelectric optical MEMS devices 200, 250 created using different annealing processes, various changes may be made to FIGS. 2A and 2B. For example, the use of the nitrogen gas anneal prior to the oxygen gas anneal may not completely eliminate the presence of discharge defects in the piezoelectric optical MEMS device 250, but it can significantly reduce the number of discharge defects. Moreover, while electrode delamination could still occur in the piezoelectric optical MEMS device 250 if an adequate number of discharge defects happen to form in a small enough area, the occurrence of electrode delamination can be substantially reduced using the nitrogen gas anneal prior to the oxygen gas anneal. As a result, product yields in a manufacturing facility can greatly increase.

FIG. 3 illustrates example results obtained using different annealing processes for piezoelectric optical MEMS devices in accordance with this disclosure. In particular, FIG. 3 illustrates three example leakage plots 302-306 associated with three different piezoelectric optical MEMS devices (denoted as wafers one, two, and three).

In FIG. 3, the leakage plot 302 is associated with a piezoelectric optical MEMS device that did not undergo a nitrogen gas anneal before an oxygen gas anneal. As a result, numerous discharge defects can form in this piezoelectric optical MEMS device, leading to a much higher-than-desired leakage current. In contrast, the leakage plots 304-306 are associated with piezoelectric optical MEMS devices that did undergo a nitrogen gas anneal before an oxygen gas anneal. As a result, those piezoelectric optical MEMS devices have much fewer discharge defects, leading to much lower leakage currents.

Although FIG. 3 illustrates examples of results obtained using different annealing processes for piezoelectric optical MEMS devices, various changes may be made to FIG. 3. For example, the leakage plots shown in FIG. 3 are for illustration only and are associated with three specific instances of piezoelectric optical MEMS devices. Other leakage plots could be obtained for other piezoelectric optical MEMS devices.

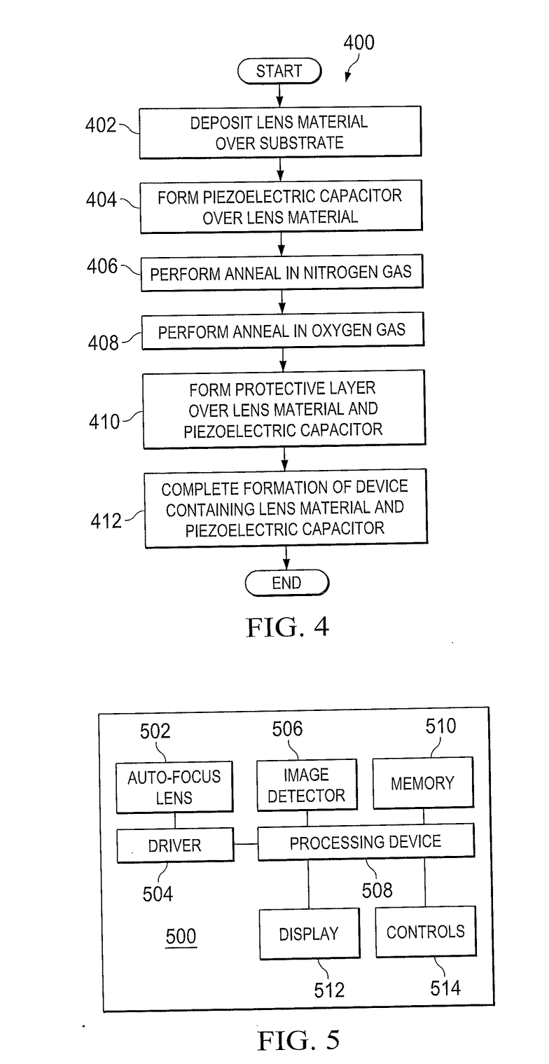

FIG. 4 illustrates an example method 400 for reducing discharge defects and electrode delamination in piezoelectric optical MEMS devices in accordance with this disclosure. For ease of explanation, the method 400 is described with respect to the piezoelectric optical MEMS device 100 of FIGS. 1A and 1B, although the method 400 could be used with any other suitable piezoelectric optical MEMS device.

As shown in FIG. 4, lens material is deposited over a substrate at step 402, and a piezoelectric capacitor is formed over the lens material at step 404. This could include, for example, depositing glass material (such as BPSG) or other lens material 102 over a silicon wafer or other substrate. This could also include depositing platinum or other metal(s) over the lens material 102 to form the electrodes 106-108. The piezoelectric material, such as a layer 110 of PZT, separates the electrodes 106-108 from one another and is formed between formation of the electrode 106 and formation of the electrode 108. Note that a seeding layer can be used to facilitate formation of the electrode 106 over the lens material 102.

An anneal of the resulting structure is performed in nitrogen gas at step 406, and an anneal of the resulting structure is performed in oxygen gas at step 408. This could include, for example, elevating the temperature around the lens material 102 and the piezoelectric capacitor 104 while flowing nitrogen gas and then oxygen gas around the structure. Each anneal could occur for any suitable length of time and at any suitable temperature, which could vary based on a number of factors (including the particular design of the piezoelectric optical MEMS device). For instance, the length and temperature of the nitrogen anneal could be selected so that substantially all of the covalent bonds between oxygen and hydrogen atoms at the interface of the top electrode 108 and the piezoelectric layer 110 and/or the interface of the bottom electrode 106 and the piezoelectric layer 110 are broken. The oxygen anneal following the nitrogen anneal can then repair the oxygen vacancies at the interface(s).

A protective layer is formed over the lens material and the piezoelectric capacitor at step 410. This could include, for example, forming an ALD or other layer of alumina or other material(s) over the lens material 102 and the piezoelectric capacitor 104. This could also include forming a protective layer 112 over the lens material 102 and the piezoelectric capacitor 104, such as a protective layer 112 having a stack that includes two silicon dioxide layers separated by a silicon oxinitride layer.

Formation of the piezoelectric optical MEMS device is completed at step 412. This could include, for example, forming electrical contacts that are electrically coupled to the electrodes 106-108, forming bond pads, and electrically coupling the electrical contacts to the bond pads. This could also include performing backend processing to remove at least part of the silicon wafer or other substrate on which the lens material 102 was deposited, thereby forming a lens. Any other or additional operations could occur to complete the formation of the piezoelectric optical MEMS device.

Although FIG. 4 illustrates one example of a method 400 for reducing discharge defects and electrode delamination in piezoelectric optical MEMS devices, various changes may be made to FIG. 4. For example, while shown as a series of steps, various steps in FIG. 4 could overlap, occur in parallel, occur in a different order, or occur any number of times.

FIG. 5 illustrates an example device 500 containing a piezoelectric optical MEMS device in accordance with this disclosure. In this example, the device 500 includes an auto-focus lens 502, which could, for example, represent the piezoelectric optical MEMS device 100 of FIGS. 1A and 1B.

In FIG. 5, the auto-focus lens 502 is coupled to a driver 504. The driver 504 provides electrical signals to the auto-focus lens 502, thereby changing the focus of the auto-focus lens 502. For example, the driver 504 could provide a voltage across the electrodes 106-108 of the MEMS device. The voltage causes the piezoelectric layer 110 to change the shape of the lens material 102, altering the focus of the lens. The driver 504 includes any suitable structure for providing electrical signals (such as one or more voltages) to an auto-focus lens.

The device 500 also includes an image detector 506, at least one processing device 508, and at least one memory 510. The image detector 506 captures images obtained using light passing through the auto-focus lens 502. The image detector 506 represents any suitable structure for capturing images, such as a charge-coupled device (CCD), a complementary metal oxide semiconductor (CMOS) device, or a charge injection device (CID). In particular embodiments, the image detector 506 includes a two-dimensional array of detection elements, such as an array of monochrome or red-green-blue (RGB) detectors.

The processing device 508 performs various functions in the device 500, such as processing information from the image detector 506 to generate captured image files or controlling the driver 504 to alter the focus of the lens 502. The processing device 508 could perform any number of functions as needed or desired, such as functions typically associated with digital cameras or video recorders. Each processing device 508 includes any suitable processing or computing device, such as a microprocessor, microcontroller, digital signal processor (DSP), field programmable gate array (FPGA), application specific integrated circuit (ASIC), or discrete logic devices. The at least one memory 510 stores instructions and data used, generated, or collected by the device 500, such as captured images. Each memory 510 includes any suitable volatile or non-volatile storage and retrieval device, such as a random access memory (RAM) or a Flash or other read-only memory (ROM).

The device 500 also includes a display 512 and one or more controls 514. The display 512 can be used for various purposes, such as to allow a user to view captured images or prepare for new images to be captured. The display 512 could also present information to the user, such as information defining available or selected options or information describing captured images. If implemented as a touchscreen, the display 512 could further receive input from the user. The controls 514 can be used to trigger various functions (such as image captures), change various options of the device 500, and generally interact with the device 500. The display 512 includes any suitable structure for presenting images or information to a user, such as a liquid crystal display (LCD) or light emitting diode (LED) display. The controls 514 include any suitable structure(s) for receiving user input, such as one or more buttons, dials, or slides.

Although FIG. 5 illustrates one example of a device 500 containing a piezoelectric optical MEMS device, various changes may be made to FIG. 5. For example, while shown as being used as part of a camera or video recorder, the piezoelectric optical MEMS device 100 could be used with any other suitable device or system in which focusing of light using a lens is desired or required.

It may be advantageous to set forth definitions of certain words and phrases used throughout this patent document. Terms such as “over” or “under,” when used with reference to components of a semiconductor device or integrated circuit, refer to relative positions of those components when viewed in particular orientations. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
performing a first anneal on a structure in nitrogen gas, the structure comprising a lens material and a piezoelectric capacitor over the lens material;
performing a second anneal on the structure in oxygen gas after performing the first anneal; and
depositing a protective layer over the structure after performing the second anneal.

2. The method of claim 1, wherein the piezoelectric capacitor comprises first and second electrodes separated by at least one piezoelectric material.

3. The method of claim 2, wherein:
the first anneal in the nitrogen gas breaks covalent bonds between oxygen and hydrogen atoms in discharge defects at one or more interfaces between one or more of the electrodes and the piezoelectric material; and
the second anneal in the oxygen gas repairs oxygen vacancies at the one or more interfaces.

4. The method of claim 2, wherein the first and second electrodes comprise at least one of: platinum, nickel, and palladium

5. The method of claim 2, wherein the at least one piezoelectric material comprises lead zirconium titanate.

6. The method of claim 1, wherein the piezoelectric capacitor comprises an aperture that exposes a portion of the lens material.

7. The method of claim 1, wherein the protective layer comprises at least one of:
silicon dioxide and silicon oxinitride.

8. A method comprising:
forming a piezoelectric capacitor over a lens material, the lens material forming a lens, the piezoelectric capacitor comprising first and second electrodes separated by at least one piezoelectric material;
performing a first anneal on the lens material and the piezoelectric capacitor in nitrogen gas;
performing a second anneal on the lens material and the piezoelectric capacitor in oxygen gas after performing the first anneal; and
depositing a protective layer over the lens material and the piezoelectric capacitor after performing the second anneal.

9. The method of claim 8, wherein:
the first anneal in the nitrogen gas breaks covalent bonds between oxygen and hydrogen atoms in discharge defects at one or more interfaces between one or more of the electrodes and the piezoelectric material; and
the second anneal in the oxygen gas repairs oxygen vacancies at the one or more interfaces.

10. The method of claim 8, wherein the first and second electrodes comprise at least one of: platinum, nickel, and palladium

11. The method of claim 8, wherein the at least one piezoelectric material comprises lead zirconium titanate.

12. The method of claim 8, wherein the protective layer comprises at least one of:
silicon dioxide and silicon oxinitride.

13. The method of claim 8, wherein the piezoelectric capacitor comprises an aperture that exposes a portion of the lens material.

14. The method of claim 8, wherein the piezoelectric capacitor is configured to change a shape of the lens material in order to change a focus of the lens.

15. A method comprising:
forming a piezoelectric optical micro-electromechanical system (MEMS) device comprising a piezoelectric capacitor over a lens material, the lens material forming a lens, the piezoelectric capacitor configured to change a shape of the lens material in order to change a focus of the lens, the piezoelectric capacitor comprising first and second electrodes separated by at least one piezoelectric material;
performing a first anneal on the piezoelectric optical MEMS device in nitrogen gas;
performing a second anneal on the piezoelectric optical MEMS device in oxygen gas after performing the first anneal; and
depositing a protective oxide layer over the lens material and the piezoelectric capacitor after performing the second anneal;
wherein the first anneal in the nitrogen gas causes the piezoelectric optical MEMS device to be substantially free of discharge defects.

16. The method of claim 15, wherein:
the first anneal in the nitrogen gas breaks covalent bonds between oxygen and hydrogen atoms in discharge defects at one or more interfaces between one or more of the electrodes and the piezoelectric material; and
the second anneal in the oxygen gas repairs oxygen vacancies at the one or more interfaces.

17. The method of claim 15, wherein:
the first and second electrodes comprise at least one of: platinum, nickel, and palladium;
the at least one piezoelectric material comprises lead zirconium titanate; and
the protective oxide layer comprises at least one of: silicon dioxide and silicon oxinitride.

18. The method of claim 15, wherein the piezoelectric capacitor comprises an aperture that exposes a portion of the lens material.

19. The method of claim 15, wherein the piezoelectric optical MEMS device comprises a portion of an auto-focus lens.

20. The method of claim 15, wherein the first anneal in the nitrogen gas further causes the piezoelectric optical MEMS device to be substantially free of electrode delamination.
